(19) United States
(12) Patent Application Publication
(10) Pub. No.: US 2017/0186935 A1
(43) Pub. Date: Jun. 29, 2017

(54) Low Temperature Deposition of Silicon Containing Layers in Superconducting Circuits

(71) Applicant: Intermolecular, Inc., San Jose, CA (US)

(72) Inventors: Joseph Anthony Bonetti, Pleasanton, CA (US); Frank Greer, Pasadena, CA (US); Wenxian Zhu, San Jose, CA (US)

(73) Assignee: Intermolecular, Inc., San Jose, CA (US)

(21) Appl. No.: 14/982,307

(22) Filed: Dec. 29, 2015

(51) Int. Cl. H01L 39/24; H01L 21/285

(52) U.S. Cl. CPC H01L 39/2493; H01L 21/28562

(57) ABSTRACT

Provided are superconducting circuits and, more specifically, methods of forming such circuits. A method may involve forming a silicon-containing low loss dielectric (LLD) layer over a metal electrode such that metal carbides at the interface of the LLD layer and electrode. The LLD layer may be formed using chemical vapor deposition (CVD) at a temperature of less than about 500° C. At such a low temperature, metal silicides may not form even though silicon containing precursors may come in contact with metal of the electrode. Silicon containing precursors having silane molecules in which two silicon atoms bonded to each other (e.g., di-silane and tri-silane) may be used at these low temperatures. The LLD layer may include amorphous silicon, silicon oxide, or silicon nitride, and this layer may directly interface one or more metal electrodes. The thickness of LLD layer may be between about 1,000 Angstroms and 10,000 Angstroms.

### BACKGROUND

When a silicon containing structure is formed over a metal structure, a barrier layer is often used to prevent silicide formation at the interface of the silicon containing structure and the metal structure. For example, a barrier layer may be used when a silicon-containing low loss dielectric (LLD) layer, such as an amorphous silicon or silicon oxide, is formed over a metal electrode in a superconducting circuit. Without a barrier layer, there is a direct contact between metal and silicon atoms and silicides can start forming when the temperature exceeds 500° C. for most common metals. Formation of silicides may be undesirable because it leads to poor loss in superconducting (radio frequency) RF circuits, for example. While forming barrier layers adds to processing time and costs and may be not possible in some application, lowering deposition temperatures is generally not possible for most conventional silicon precursors, such as mono-silane.

### SUMMARY

Provided are superconducting circuits and, more specifically, methods of forming such circuits. A method may involve forming a silicon-containing LLD layer over a metal electrode such that metal carbides at the interface of the LLD layer and electrode. The LLD layer may be formed using chemical vapor deposition (CVD) at a temperature of less than about 500° C. At such a low temperature, metal silicides may not form even though silicon containing precursors may come in contact with metal of the electrode. Silicon containing precursors having silane molecules in which two silicon atoms bonded to each other (e.g., di-silane and tri-silane) may be used at these low temperatures. The LLD layer may include amorphous silicon, silicon oxide, or silicon nitride, and this layer may directly interface one or more metal electrodes. The thickness of the LLD layer may be between about 1,000 Angstroms and 10,000 Angstroms.

In some embodiments, a method of forming a superconducting circuit involves providing a metal layer. The metal layer may be a part of a Josephson junction, for example. The method continues with forming an LLD layer over the metal layer using CVD. The metal layer is kept at a temperature below about 525° C. while forming the LLD layer. The LLD layer includes one of amorphous silicon, silicon oxide, or silicon nitride. The dielectric layer is formed using a silicon containing precursor. For example, the silicon containing precursor may include silane molecules in which two silicon atoms bonded to each other, such as di-silane or tri-silane. Without being restricted to any particular theory, it is believed that having one or more silicon-silicon bonds in the silicon containing precursor allows using lower deposition temperatures than, for example, when a silane is used. In some embodiments, the silane molecules of the silicon containing precursor have no silicon atoms each bonded with three or more other silicon atoms, such as in a higher level poly-silane.

In some embodiments, the LLD layer directly interfaces the metal layer. The interface between the metal layer and the LLD layer may be substantially free of a metal silicide. The lack of metal silicides at the interface may be attributed to low deposition temperatures. In some embodiments, the metal layer includes one of niobium or aluminum. The LLD layer may include amorphous silicon or silicon oxide.

In some embodiments, the chemical vapor deposition used to form the LLD layer is plasma enhanced chemical vapor deposition (PECVD). The metal layer may be kept at the temperature below about 500° C. while forming the LLD layer. More specifically, the metal layer may be kept at the temperature between about 475° C. and 500° C. while forming the LLD layer.

In some embodiments, providing the metal layer involves forming the metal layer using physical vapor deposition (PVD). Forming of the metal layer and forming the LLD layer may be performed in situ, for example. The LLD layer may have a thickness of between about 1,000 Angstroms and 10,000 Angstroms.

These and other embodiments are described further below with reference to the figures.

### BRIEF DESCRIPTION OF THE DRAWINGS

FIGS. 1A and 1B are schematic representations of a Josephson junction, in accordance with some embodiments.

FIG. 2 is a process flowchart corresponding to a method of forming a superconducting circuit, in accordance with some embodiments.

FIG. 3 illustrates X-ray crystallography diffraction (XRD) experimental analysis data for different amorphous silicon samples formed on niobium substrates.

FIG. 4 illustrates electronic spin resonance (ESR) data for various samples

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

Typically, integrated circuits combine multiple layers, including conductive, semi-conductive and/or insulating layers. For example, superconducting devices, such as Josephson junctions, include two metal electrodes separated by a thin insulating dielectric. Integrated circuits may be a part of larger, multilayer devices to serve a particular purpose. For example, Josephson junctions can be used in superconducting quantum interference devices (SQUIDs), superconducting tunnel junction detectors (STJs), Rapid Single Flux Quantum (RSFQ) devices, single-electron transistors, and other applications. In some embodiments, integrated circuits use insulating layers, including silicon-containing insulating layers, such as LLD layers, to electrically insulate metal electrodes and provide additional strength to the device. However, it can be challenging to create silicon-containing LLD layers without forming silicide.

Silicide formation at an interface of a silicon-containing structure and a metal structure is undesirable in many applications, such as superconducting circuits, when a silicon-containing LLD layer is formed over a metal electrode, for example. The silicon-containing LLD layer and other similar structures are often formed using CVD, during which a silicon containing precursor is flown into a deposition chamber. The silicon containing precursor either decomposes or reacts with another gas at a deposition surface maintained at an elevated temperature. Initially, the deposition surface may be an exposed surface of the metal structure when, for example, a barrier layer is not used. Considering that the silicon containing precursor needs to be a highly reactive substrates and that deposition needs to be performed at a higher temperature, the silicon containing precursor may also react with metal of the deposition surface thereby forming silicides.

The silicon-containing precursor most commonly used for growing amorphous silicon and silicon oxide is mono-silane (SiH₄). When amorphous silicon is grown on niobium using mono-silane (SiH₄), the deposition temperature may need to be about 550° C. to achieve any reasonable deposition rate. At 550° C. (and above), silicides readily form on surfaces of many superconducting metal electrodes, such as elemental niobium electrode and elemental titanium electrode. In other words, at a temperature of 550° C. and above, mono-silane (SiH₄) will react with niobium and/or tantalum and quickly form silicide while a silicon containing layer is being deposited directly on the superconducting metal electrode. Formation of silicides at an interface of an LLD later and electrode is not desirable as its leads to poor loss in the superconducting circuit. In many superconducting circuits the dielectric layer is used to form RF micro-strips. The loss at cryogenic temperatures in these micro-strips can be dominated by loss in the dielectric. The mechanism for this loss is known to be from two-level system fluctuations from defects such as dangling bonds. One having ordinary skills in the art would understand that, silicides are known to produce a large amount of these two-level system defects and create substantial loss.

It has been found that amorphous silicon can be grown over a niobium structure (e.g., an LLD formed over a niobium electrode) using tri-silane (Si₃H₈) as a precursor instead of mono-silane (SiH₄). As a result of replacing mono-silane (SiH₄) with tri-silane (Si₃H₈), the deposition temperature can be lowered from 550° C. to 515° C. or even down to about 425° C. A combination of tri-silane (Si₃H₈) and a lower deposition temperature led to effectively no silane formed at the interface of amorphous silicon and niobium structure. X-ray photoelectron spectroscopy (XPS) analysis of amorphous silicon samples formed on niobium surfaces formed using tri-silane (Si₃H₈) at a lower temperature of 515° C. showed no evidence of niobium-silicide. Furthermore, the quality of amorphous silicon produced using tri-silane (Si₃H₈) at a lower temperature of 515° C. is at least as good or, in some instances, even better than that produced using mono-silane (SiH₄) at from 550° C. Specifically, a high electron spin resonance (ESR) signal correlates with high loss, while a low ESR correlates with low loss. The ESR signal corresponding to a sample formed using tri-silane (Si₃H₈) at a lower temperature of 515° C. was actually lower than that corresponding to a sample formed mono-silane (SiH₄) at from 550° C. In other words, using tri-silane (Si₃H₈) and lowering the deposition temperature of 515° C. effectively eliminated silicides at the interface and substantially reduced the loss.

### Examples of Superconducting Circuits

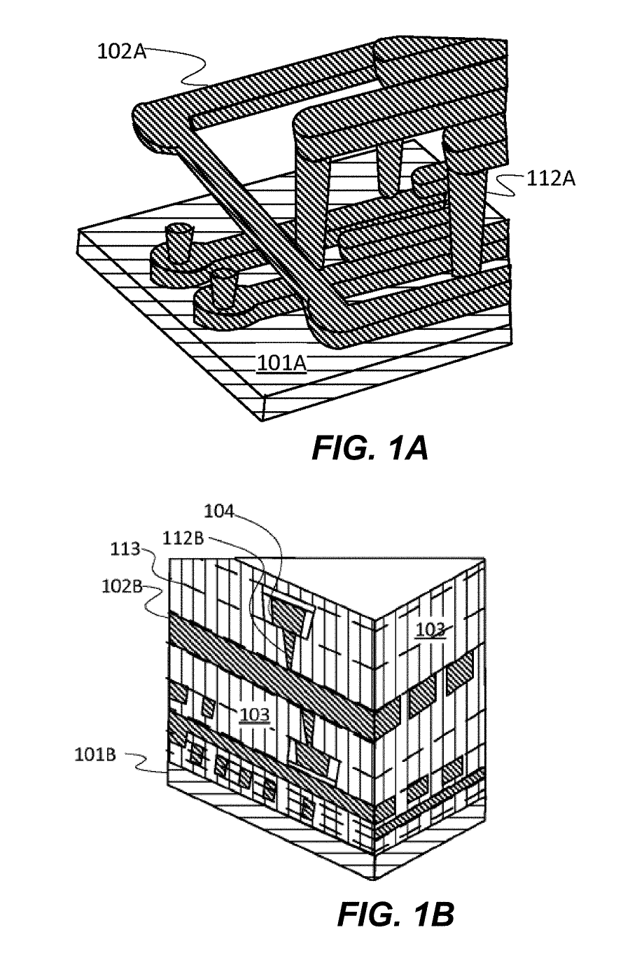

FIGS. 1A and 1B conceptually illustrate electrodes and LLD layers. Specifically, FIG. 1A illustrates multiple layers of conductive structures, which may be also referred to as interconnects, without showing an LLD layer. This figure is presented simply to better visualize the three-dimensional network of electrodes 102A and vias 112A built up on substrate 101A. Substrate 101A may have other LLD layers and conductive structures below those shown. Electrode 102A or vias 112A may be formed by forming a blanket conductive layer followed by etching to form a separate conductive path. Suitable methods for forming these electrodes and vias may include, but not limited to, PVD,

Atomic Layer Deposition (ALD), CVD, Electron Beam Physical Vapor Deposition (EBPVD), Pulsed Laser Deposition (PLD), evaporative deposition, cathodic arc deposition, thermal spray coating, sputter deposition, electroplating, photolitography, and so forth. Suitable methods for selective etching of the conductive layers include, but not limited to, wet etching, anisotropic wet etching, plasma etching, dry etching, reactive ion etching (RIE), hydrofluoric acid or buffered oxide etchant (BOE) etching.

In superconducting microwave devices, electrodes 102A or vias 112A may be any suitable superconducting material, such as aluminum (Al), aluminum alloys, aluminum nitrides, niobium (Nb), niobium alloys, niobium nitrides, ceramic superconductors, or organic superconductors. Substrate 101A may include a silicon or silicon oxide layer. In some embodiments, substrate 101A can be a part of a wafer, die, or integrated circuit.

FIG. 1B is a schematic cutaway view of several interconnect and device layers. Here, similarly to FIG. 1A, there are shown substrate 101B, such as silicon-based wafer, electrically conductive electrodes 102B, electrically conductive interconnects or vias 112B, all of which can be fabricated using the same methods as described above with reference to FIG. 1A. As further shown in FIG. 1B, there is provided LLD layer 103, which is disposed between different conductive structures, but within the same multiplayer stack of a superconducting circuit. According to various embodiments, the multiplayer stack may include a single LLD layer 103, but in other embodiments, there can be a plurality of LLD layers 103. Multiple LLD layers 103 can contact each other (i.e., lay over each other). For example, heavy dotted lines 113 shown in FIG. 1B delineate separately formed LLD layers 103. Alternatively, some or all LLD layers 103 can be spaced from each other or located on different levels. As described herein, each LLD layer 103 may include amorphous silicon layer fabricated using tri-silane as a precursor. Typically, the thickness of LLD layer 103 is in a range between about 1,000 Angstroms to about 10,000 Angstroms. In this disclosure, the term “about” shall mean a reasonable deviation of a value accompanying this term. If it is not specified otherwise, the term “about” may refer to a variation of 10% from an indicated value. In the case of a range of values, the term “about” may refer to a 10% variation from both the lower and upper limits of the range.

The illustrated structures also include electrical components 104 such as discrete or embedded transistors, capacitors, switches, resistors, resonators. In superconducting embodiments, components 104 may include Josephson junctions. In some embodiments, electrodes 102B are parts of Josephson junctions. For example, Josephson junctions may include electrode 102B interfacing with a thin dielectric layer to exhibit superconducting properties. Electrode 102B can include a metal, such as niobium or aluminum, nitrides thereof, alloys, or another suitable material. Electrodes 102B have a thickness of between about 1500A and 3000A or, more specifically, between about 1500A and 3000A. In some embodiments, the thickness is greater than a so called the London penetration depth, which for niobium is about 1200A. There may be no upper bound on the thickness from the device performance perspective. However, the upper bound may be established by device packaging and other considerations. The thin dielectric layer may include aluminum oxide. Other examples of suitable dielectric materials include but not limited to, magnesium oxide, lanthanum oxide, and other metal oxides. In some embodiments, the thin dielectric layer has a thickness of between about 5 Angstroms and 50 Angstroms or, more specifically, between about 10 Angstroms and 30 Angstroms.

### Examples of Forming Superconducting Circuits

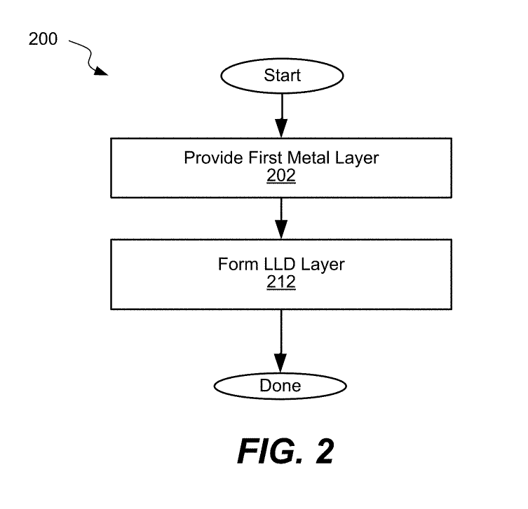

FIG. 2 is a process flowchart corresponding to method 200 of forming a superconducting circuit, in accordance with some embodiments. Method 200 may commence with providing a first metal layer during operation 202. The first metal layer can be provided on a substrate, such as silicon or silicon oxide. Alternatively, the first metal layer can be provided on a dielectric layer or semiconducting layer depending on a particular application. Some examples of the first metal layer include metal layers 102A and 102B described above and shown in FIG. 1A and FIG. 1B. The first metal layer may include aluminum, aluminum alloy, aluminum nitride, niobium, niobium alloy, niobium nitride, ceramic superconductor, organic superconductor, or any combination thereof. Accordingly, the first metal layer exhibits electrical conducting properties.

The shape and dimensions of the first metal layer may vary depending on an application. In one example, the first metal layer may include a metal stripe. In another example, the first metal layer may be selectively patterned and include one or more turns. In yet more embodiments, the first metal layer may be combined with or include interconnect structures, such as vias 112A and 112B shown in FIG. 1A and FIG. 1B, accordingly. The interconnect structures may have cylindrical shape, tapered shape, conical shape, or any combination thereof. In some embodiments, the first metal layer may be a part of a device, such as discrete or embedded resistors, transistors, capacitors, switches, inductance, and so forth. In superconducting embodiments, the first metal layer may be a part of one or more Josephson junctions, for example.

The first metal layer can be fabricated using a wide range of deposition and patternmaking methods. Some suitable methods for depositing the first metal layer include, but not limited to, PVD, ALD, CVD, EBPVD, PLD, evaporative deposition, cathodic arc deposition, thermal spray coating, sputter deposition, electroplating, photolitography, and so forth. Suitable methods for selective patterning of the first metal layer include, but not limited to, wet etching, anisotropic wet etching, plasma etching, dry etching, RIE, hydrofluoric acid or BOE etching.

Still referring to FIG. 2, method 200 may proceed with forming a LLD layer over the first metal layer at operation 212. One example of the LLD layer include LLD layer 103 shown in FIG. 1B. The LLD layer may include amorphous silicon or silicon oxide. Typically, the thickness of LLD layer 103 is in a range between about 1,000 Angstroms to about 10,000 Angstroms. The geometry of the LLD layer can be as simple as a thin layer, but in other embodiments the LLD layer can be patterned or it can encompass, cover or embed other elements of the superconducting circuit. For example, the LLD layer can encompass metal electrodes as shown in FIG. 1B. Furthermore, operation 212 may include forming a single LLD layer or a plurality LLD layers. If multiple LLD layers are provided, the geometry of each LLD layer is not necessarily the same. In certain embodiments, each one of a plurality of LLD layers may have its own shape, dimensions, and geometry. Moreover, each one of the plurality of LLD layers may have its unique location within the superconducting circuit.

The LLD layer can be fabricated from a precursor using, for example, CVD process, although other deposition methods can be also used. Particularly, the first metal layer is kept at a temperature below about 525° C. while forming the LLD layer. The LLD layer includes one of amorphous silicon, silicon oxide, or silicon nitride. The precursor can include a silicon-containing material including silane molecules. For example, the silicon containing precursor may include silane molecules in which two silicon atoms bonded to each other forming di-silane or tri-silane. In other embodiments, the silicon-containing precursor can include a combination of tri-silane and di-silane. The ratio of tri-silane to di-silane in the precursor can be predetermined and be in a range from about 1:1 to about 100:1. Without being restricted to any particular theory, it is believed that having one or more silicon-silicon bonds in the silicon containing precursor allows using lower deposition temperatures than, for example, when a silane is used. In some embodiments, the silane molecules of the silicon-containing precursor have no silicon atoms each bonded with three or more other silicon atoms, such as in a higher level poly-silane.

In some embodiments, the LLD layer directly interfaces the first metal layer. The interface between the first metal layer and the LLD layer may be substantially free of a metal silicide. The lack of metal silicides at the interface may be attributed to low deposition temperatures. For purposes of this disclosure, the term “substantially” used in the context of the lack of metal silicide molecules within the LLD layer or the interface between the LLD layer and the first metal layer shall mean that the level of metal silicide molecules in these layers does not negatively affect any operating characteristics of the superconducting circuit. For example, the term “substantially” in this context can mean that there are no more than 10% of metal silicide molecules in the LLD layer or within the interface between the LLD layer and the first metal layer.

In some embodiments, the CVD method used to form the LLD layer is plasma enhanced chemical vapor deposition (PECVD). The metal layer may be kept at the temperature below about 500° C. while forming the LLD layer. More specifically, the first metal layer may be kept at the temperature between about 475° C. and 500° C. while forming the LLD layer. In some embodiments, providing the metal layer involves forming the metal layer using PVD process. Forming of the metal layer and forming the LLD layer may be performed in situ, for example.

### Experimental Results

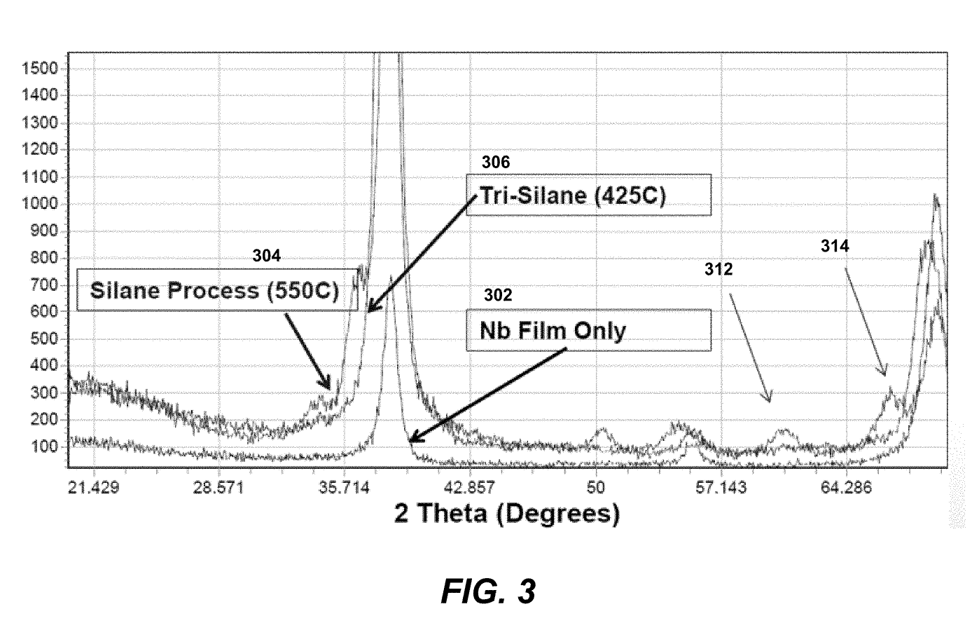

Multiple experiments have been conducted to determine how a tri-silane precursor allows creating a LLD layer over a metal layer without forming metal silicides. Particularly, FIG. 3 includes X-ray crystallography diffraction (XRD) graphs showing the dependency of signal intensity measured in arbitrary units (a.u.) from a measurement angle (2 Theta). The XRD graphs shown in FIG. 3 represent three experiments as follows. Graph 302 illustrates a first XRD pattern obtained from a single niobium film deposited over a substrate and without a LLD layer. The niobium layer was fabricated as described above with reference to operation 202 shown in FIG. 2. Graph 304 illustrates a second XRD pattern obtained from a first superconducting circuit having a substrate with a niobium film, over which a LLD layer is deposited using a conventional method based on the introduction of mono-silane precursor at the deposition temperature of about 550° C. Finally, graph 306 illustrates a third XRD pattern obtained from a second superconducting circuit fabricated using method 200 as described above. Specifically, the second superconducting circuit includes a niobium film deposited over a substrate using, for example, operation 202. There is also a LLD layer deposited on top of the niobium film using operation 212 as described above, which implies that the LLD layer is grown in presence of tri-silane precursor at lowered deposition temperature of about 425° C. In this disclosure, the term “deposition temperature” shall mean a temperature, at which a metal layer (or a metal layer with a substrate) is maintained during fabrication of the LLD layer.

In all experiments, the substrate included a silicon oxide substrate with the thickness of about 1,000 Angstroms. Further, in all experiments, the niobium film had the thickness of about 500 Angstroms. In the first and second superconducting circuits (i.e., represented by graphs 304 and 306), the LLD layer included amorphous silicon and the thickness of the LLD layer was about 150 Angstroms.

As can be seen from FIG. 3, the second XRD pattern (which corresponds to graph 304 associated with the first superconducting circuit) includes two peaks 312 and 314. These peaks 312 and 314 accord to niobium silicides, such as NbSi₂ and Nb₃Si, which have been created as a result of using the conventional deposition method involving the mono-silane precursor deposited at a high deposition temperature of about 550° C. To the contrary, the third superconducting circuit represented by the third XRD pattern (graph 306) does not yield any niobium silicide peaks, such as peaks 312 and 314. In other words, the experimental results demonstrate that the method for fabricating a LLD layer over a niobium film using a tri-silane precursor at a low deposition temperature of about 425° C. prevents the formation of niobium silicides inside the LLD layer or in the interface between the LLD layer and the niobium film. The lack of silicides further allows reducing the dielectric losses, thereby improving operating characteristics of the superconducting circuit.

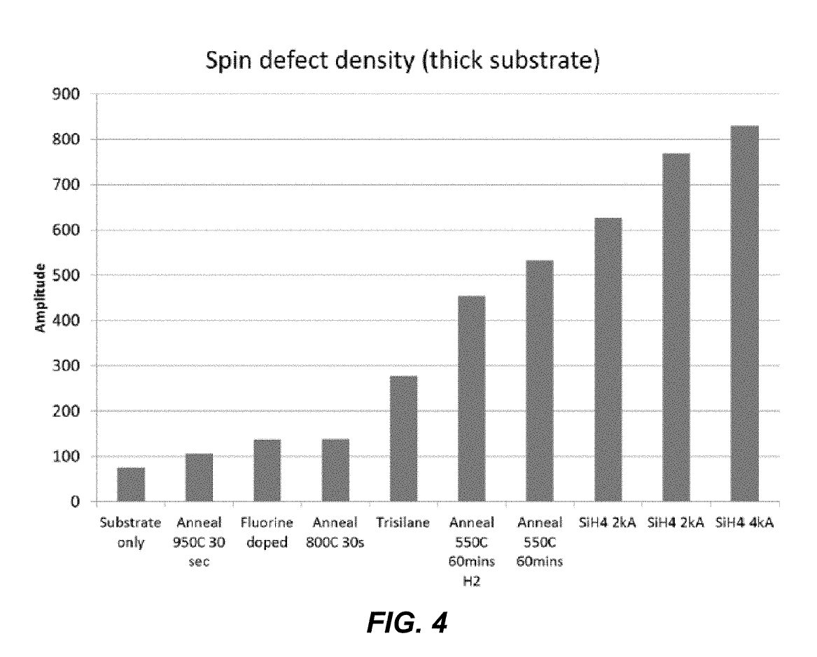

FIG. 4 illustrates electronic spin resonance (ESR) data for various samples. Specifically, FIG. 4 illustrates that ESR signal corresponding to a sample formed using tri-silane (Si₃H₈) at a lower temperature of 515° C. was actually lower than that corresponding to a sample formed mono-silane (SiH₄) at from 550° C.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses.

Accordingly, the present embodiments are to be considered as illustrative and not restrictive.

what is claimed is:

1. A method of forming a superconducting circuit, the method comprising:
providing a metal layer,
wherein the metal layer is a part of a Josephson junction; and
forming a low loss dielectric (LLD) layer over the metal layer using chemical vapor deposition (CVD) ,
wherein the metal layer is kept at a temperature below about 525° C. while forming the low loss dielectric layer,
wherein the low loss dielectric layer comprises one of amorphous silicon, silicon oxide, or silicon nitride, and
wherein the dielectric layer is formed using a silicon containing precursor,
wherein the silicon containing precursor comprises silane molecules in which two silicon atoms bonded to each other.

2. The method of claim 1, wherein the silicon containing precursor is one of di-silane or tri-silane.

3. The method of claim 1, wherein the silicon containing precursor is tri-silane.

4. The method of claim 1, wherein the silane molecules have linear silicon-to-silicon bonds.

5. The method of claim 1, wherein the low loss dielectric layer directly interfaces the metal layer.

6. The method of claim 5, wherein an interface between the metal layer and the low loss dielectric layer is substantially free of a metal silicide.

7. The method of claim 6, wherein the metal layer comprises one of niobium or aluminum.

8. The method of claim 6, wherein the metal layer comprises niobium.

9. The method of claim 8, wherein the low loss dielectric layer comprises amorphous silicon.

10. The method of claim 8, wherein the low loss dielectric layer comprises silicon oxide.

11. The method of claim 1, wherein the chemical vapor deposition is plasma enhanced chemical vapor deposition (PECVD).

12. The method of claim 1, wherein the metal layer is kept at the temperature below about 500° C. while forming the low loss dielectric layer.

13. The method of claim 1, wherein the metal layer is kept at the temperature between about 475° C. and 500° C. while forming the low loss dielectric layer.

14. The method of claim 1, wherein providing the metal layer comprises forming the metal layer using physical vapor deposition (PVD).

15. The method of claim 14, wherein forming the metal layer and forming the low loss dielectric layer are performed in situ.

16. The method of claim 1, wherein the low loss dielectric layer comprises amorphous silicon.

17. The method of claim 1, wherein the low loss dielectric layer comprises silicon oxide.

18. The method of claim 1, wherein the low loss dielectric layer has a thickness of between about 1,000 Angstroms and 10,000 Angstroms.

19. The method of claim 1, wherein the metal layer comprises one of niobium or aluminum.

20. The method of claim 1, wherein the metal layer comprises niobium.
